(19) United States
(12) Patent Application Publication
(10) Pub. No.: US 2015/0364553 A1
(43) Pub. Date: Dec. 17, 2015

(54) OXIDE FOR SEMICONDUCTOR LAYER OF THIN FILM TRANSISTOR, THIN FILM TRANSISTOR, AND DISPLAY DEVICE

(71) Applicant: KABUSHIKI KAISHA KOBE SEIKO SHO (KOBE STEEL, LTD.), Kobe-shi, Hyogo (JP)

(72) Inventors: Shuji KOSAKA, Kobe-shi (JP); Kazushi HAYASHI, Kobe-shi (JP)

(73) Assignee: Kabushiki Kaisha Kobe Seiko Sho (Kobe Steel, Ltd.), Kobe-shi, Hyogo (JP)

(21) Appl. No.: 14/765,507

(22) PCT Filed: Feb. 27, 2014
(86) PCT No.: PCT/JP14/54959

§ 371 Date: Aug. 3, 2015

(30) Foreign Application Priority Data
Mar. 8, 2013 (JP) 2013-047367

(51) Int. Cl. H01L 29/24; C01G 19/00; H01L 29/786

(52) U.S. Cl. CPC H01L 29/24; H01L 29/78693; C01G 19/006; C01P 2006/40

(57) ABSTRACT

With respect to this oxide for a semiconductor layer of a thin film transistor, metal elements that constitute the oxide comprise In, Sn, Ga, and Zn, the oxygen partial pressure when forming the oxide film as the semiconductor layer of the thin film transistor is 15 volume % or lower (not including 0 volume %), the defect density of the oxide satisfies 2×10¹⁶ cm⁻³ or less, and the mobility satisfies 6.2 cm²/Vs or more.

### FIELD OF TECHNOLOGY

The present invention relates to an oxide for a semiconductor layer in a thin film transistor (also referred to TFT hereinbelow), a thin film transistor, and a display device. Specifically, it relates to an oxide for a semiconductor layer in a TFT which is preferably used in a display device such as a liquid crystal display and an organic EL (Electro Luminescence) display, a TFT having the oxide for a semiconductor layer, and a display device having the TFT.

### BACKGROUND ART

As compared with widely used amorphous silicon (a-Si), amorphous (non-crystalline) oxide semiconductors have high carrier mobility, wide optical band gaps, and film formability at low temperatures, and therefore, have highly been expected to be applied for next generation displays, which are required to have large sizes, high resolution, and high-speed drives; and for resin substrates having low heat resistance; and others.

In the oxide semiconductors, an amorphous oxide semiconductor comprising indium, tin, gallium, zinc and oxygen (In—Sn—Ga—Zn—U, which may hereinafter be referred to as “ITGZO”) is preferably used for a semiconductor layer in a TFT because of its high carrier mobility.

When an oxide semiconductor is used as a semiconductor layer of a thin film transistor, it is very important for the oxide semiconductor to have not only a high carrier concentration (mobility) but also a low density of defects in the semiconductor layer.

Patent document 1, for example, discloses a method of subjecting a semiconductor substrate consisting of an oxide semiconductor to a water vapor atmosphere after subjecting the semiconductor substrate to hydrogen plasma or hydrogen radicals for the purpose of decreasing defects due to non-uniform composition and improving a transfer characteristic of the oxide semiconductor.

### PRIOR ART DOCUMENTS

### Patent Document

Patent Document 1: Japanese Patent Laid-open Publication No. 2011-171516

### SUMMARY OF THE INVENTION

### Problems to be Solved by the Invention

One object of the present invention is to provide an oxide for a semiconductor layer in a thin film transistor having a high mobility and a decreased density of defects. Another object of the present invention is to provide a thin film transistor and a display device, which comprise the oxide for the semiconductor layer.

### Means for Solving the Problems

An oxide of the present invention, which can solve the above-mentioned problems, is configured to be used as a semiconductor layer in a thin film transistor, in which metal elements constituting the oxide comprise In, Sn, Ga, and Zn; partial pressure of oxygen when forming the oxide as the semiconductor layer in the thin film transistor is 15 volume % or lower (not including 0 volume %); and defect density of the oxide satisfies 2×10¹⁶ cm⁻³ or smaller, and the mobility satisfies 6.2 cm²/Vs or larger.

In a preferred embodiment of the present invention, the oxide satisfies relations of 3≦[In]≦25, 15≦[Sn]≦30, 10≦[Ga]≦50, 30≦[Zn]≦60 wherein [In], [Sn], [Ga], and [Zn] respectively represent content ratios (in atomic %) of each of the elements relative to the total content of all the metal elements other than oxygen.

The present invention also encompasses a thin film transistor comprising any of the oxides for semiconductor layer as a semiconductor layer of the thin film transistor.

The present invention further encompasses a display device having the thin film transistors as described above.

### Effects of the Invention

The present invention can provide an oxide configured to be used for a semiconductor layer of a thin film transistor having a high mobility and a decreased density of defects. A display of high reliability can be obtained by using the thin film transistor comprising the oxide for the semiconductor layer according to the present invention.

### BRIEF DESCRIPTION OF DRAWING

FIG. 1 is a schematic cross-sectional view for explaining a thin film transistor of the present invention.

FIG. 2 is a schematic cross-sectional view for explaining a MIS (Metal Insulator Semiconductor) structure element for measurement of defect density by ICTS method used in Example.

FIG. 3 are C-V (capacitance-voltage) curves to determine reverse bias and pulse bias in the ICTS measurement for each partial pressures of oxygen (4 volume %, 10 volume %, 20 volume %, 30 volume % in Example.

FIG. 4 are graphs showing results of drain current-gate voltage characteristics (I_{d}-V_{g} characteristics) curves when partial pressure of oxygen was varied in a range from 4 to 30 volume % in Example.

FIG. 5 is a plot showing relations between partial pressure of oxygen and defect density or mobility in Example.

### MODE FOR CARRYING OUT THE INVENTION

In order to provide an oxide used for a semiconductor layer in a thin film transistor having a high mobility and a decreased density of defects, the present inventors have made studies particularly on In—Sn—Ga—Zn—O (ITGZO) in which metal elements constituting the oxide are In, Sn, Ga, and Zn. Measurement of the defect density was conducted by using ICTS (Isothermal Capacitance Transient Spectroscopy) method.

It turned out that just measuring drain current-gate voltage characteristics (I_{d}-V_{g} characteristics) and deriving mobility of TFT in conventional way are not sufficient. Specifically, it was found that there can be a case in which even TFTs apparently having similar I_{d}-V_{g} characteristics have different defect densities measured by ICTS method accompanying different mobilities. That is, it was found that the defect density must be accurately figured out in order to control the mobility.

As a result of further investigation, the present invention has been completed by finding that both high mobility and low defect density can be achieved by appropriately controlling partial pressure of oxygen when depositing ITGZO film.

The ICTS method used for measuring defect density is briefly explained here.

The ICTS method is one kind of capacitance transient spectroscopy methods. It is known as one method to accurately measure localized potentials such as an interface trap and a bulk trap which are formed by impurity atoms and defects in the semiconductor layer. Since thickness of the depletion layer corresponds to the reciprocal of temporal change of junction capacitance C(t), information on localized levels are obtained by measuring transient capacitance of (t) in the capacitance transient spectroscopy methods. Other than the ICTS method, DLTS (Deep Level Transient Spectroscopy) method is also included in the measurement methods of transient capacitance. Both share an identical measurement principle but their measurement methods are different. In the DLTS method, DLTS signals are acquired while changing temperature of specimen. In the ICTS method, on the other hand, emission time constant is varied by modulating applied pulse at a constant temperature to obtain the same information as the DLTS signals. A technology to suppress defect density low and to obtain high mobility by way of detailed measurement of the defect density in an oxide semiconductor such as ITGZO by the ICTS method has never been proposed.

The present invention is described in detail hereinbelow.

As described above, in the oxide for a semiconductor layer in a thin film transistor according to the present invention, the metal elements constituting the oxide comprise In, Sn, Ga, and Zn and the partial pressure of oxygen when forming the oxide (ITGZO) as the semiconductor layer in the thin film transistor is 15 volume % or lower (not including 0 volume %). Further, the defect density of the oxide is as low as 2×10¹⁶ cm⁻³ or smaller, and the mobility satisfies as high level as 6.2 cm²/Vs or larger. According to the present invention, by controlling defect density low by way of appropriately controlling partial pressure of oxygen when forming the ITGZO film, mobility can be enhanced to a still higher level and defect density can be suppressed to a still lower level.

The oxide preferably satisfies relations of 3≦[In]≦25, 15≦[Sn]≦30, 10≦[Ga]≦50, 30≦[Zn]≦60 wherein [In], [Sn], [Ga], and [Zn] respectively represent content ratios (in atomic %) of each of the elements relative to the total content of all the metal elements other than oxygen.

The metal elements have actions as outlined in the following.

Firstly, In is an element having an effect to increase carrier and mobility. [In] is preferably equal to 3 or larger, more preferably equal to 8 or larger, and even more preferably equal to 13 or larger. If the amount of In is excessively large, however, the oxide becomes conductive due to excess carriers as well as the stress stability is deteriorated. [In] is preferably equal to 25 or smaller, more preferably equal to 22 or smaller, and even more preferably equal to 18 or smaller.

Sn is an element having an effect to improve chemical resistance such as wet etching durability of the oxide semiconductor layer. [Sn] is preferably equal to 15 or larger, more preferably equal to 16 or larger, and even more preferably equal to 18 or larger. If the amount of Sn is excessively large, however, etching workability is deteriorated. [Sn] is preferably equal to 30 or smaller, more preferably equal to 25 or smaller, and even more preferably equal to 21 or smaller.

Ga is an element having an effect to stabilize the amorphous structure and stress stability of the oxide semiconductor. [Ga] is preferably equal to 10 or larger, more preferably equal to 13 or larger, and even more preferably equal to 17 or larger. If the amount of Ga is excessively large, however, mobility is decreased. [Ga] is preferably equal to 50 or smaller, and more preferably equal to 30 or smaller.

Zn is considered effective to make amorphous structure stable and contributes to improving the stress stability. [Zn] is preferably equal to 30 or larger, more preferably equal to 40 or larger, and even more preferably equal to 45 or larger. If the amount of Zn is excessively large, however, there may be a case in which the oxide semiconductor layer crystallizes or residues are generated when it is etched. [Zn] is preferably equal to 60 or smaller, more preferably equal to 55 or smaller, and even more preferably equal to 50 or smaller.

The oxide of the present invention satisfies the requirements of defect density of 2×10¹⁶ cm⁻³ or smaller and mobility of 6.2 cm²/Vs or larger. The lower the defect density is, the more preferable. The defect density is preferably equal to 1.8 cm⁻³ or smaller, and more preferably equal to 1.5 cm⁻³ or smaller. On the other hand, the larger the mobility is, the more preferable. The mobility is preferably equal to 6.8 cm²/Vs or larger, and more preferably equal to 7.5 cm²/Vs or larger.

The oxide is preferably deposited by a sputtering method using a sputtering target. By employing a sputtering method, it is possible to easily form a thin film having excellent in-plane uniformity in terms of composition and thickness.

In order to obtain the oxide having appropriately controlled defect density and mobility as in the present invention, partial pressure of oxygen, that is volume ratio of oxygen to the entire atmospheric gas is to be controlled to 15 volume % when forming the oxide as a semiconductor layer of the thin film transistor. From the point of view to suppressing the defect density as small as possible and enhancing the mobility as large as possible in the oxide, the lower the partial pressure of oxygen is, the more preferable. The partial pressure of oxygen is preferably equal to 10 volume % or smaller, and more preferably equal to 4 volume % or smaller. In order to circumvent a problem of converting to be a conductor, the present invention requires adding oxygen for the deposition of the oxide semiconductor. That is, the partial pressure of oxygen does not include 0 volume %. It is preferably equal to 0.4 volume % or larger, and more preferably equal to 1 volume % or larger.

The present invention also encompasses a thin film transistor comprising any of the oxide used for a semiconductor layer as a semiconductor layer of the thin film transistor. For the fabrication of the thin film transistor, usually used methods may be adopted. As explained hereinabove, nothing is particularly limited other than controlling partial pressure of oxygen during forming the semiconductor layer.

Thickness of the semiconductor layer is preferably equal to 30 nm or larger. If the thickness is too thin, sufficient operation current cannot be secured. In addition, variations are caused in sputtering deposition and transistor characteristics become non-uniform, which cause a problem of unevenness in display device. The lower limit is more preferably equal to 35 nm or larger. On the other hand, the upper limit is preferably equal to 200 nm or smaller. When the film becomes thick, the depletion layer does not extend sufficiently even by varying the gate voltage. Consequently, the transistor cannot be turned off, that is, the current cannot be cut off. Even when the transistor is turned off, the required gate voltage significantly shifts to negative side as compared to the normal voltage, which is not appropriate for operation of display device. The upper limit is more preferably equal to 150 nm or smaller, and even more preferably equal to 80 nm or smaller.

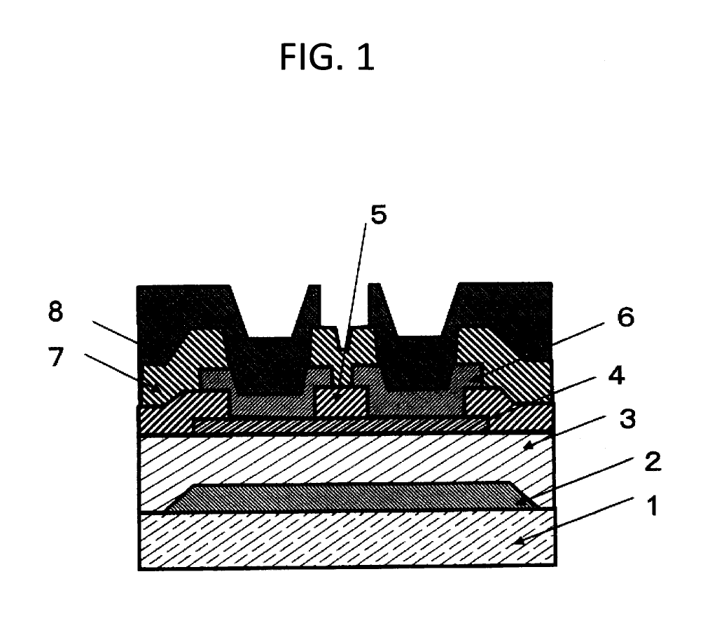

Referring to the TFT shown in FIG. 1, embodiments of a fabrication process of the above-described TFT are explained in the following. FIG. 1 and the following fabrication process demonstrate one example of preferred embodiments of the present invention, but it is not intended that the present invention be limited thereto. FIG. 1, for example, shows a TFT structure of a bottom gate type; however, TFTs are not limited thereto, and TFTs may be those of the top gate type, each having a gate insulator film and a gate electrode successively on above an oxide semiconductor layer.

As shown in FIG. 1, a gate electrode 2 and a gate insulator film 3 are formed on the substrate 1, and an oxide semiconductor layer 4 is formed further thereon. On the oxide semiconductor layer 4, a passivation film 5 is formed. A source-drain electrode 6 is formed thereon. A surface passivation film 7 is formed further thereon, and a transparent conductive film 8 formed on the outermost surface. The transparent conductive film 8 is electrically connected to the source-drain electrode 6. An insulator film such as a silicon oxide film (SiO₂ film) is used for the passivation film 5.

The method of forming the gate electrode 2 and the gate insulator film 3 on the substrate 1 is not particularly limited, and any of the methods usually used can be employed. The kinds of the gate electrode 2 and the gate insulator film 3 are not particularly limited, and those which are widely used can be adopted. For example, a metal thin film such as Al and Cu, and their alloy thin film, or a Mo thin film or the like used in an example described below can be used for the gate electrode 2. Typical examples of the gate insulator film 3 may include a silicon oxide film (SiO₂ film), a silicon nitride film (SiN film), and a silicon oxynitride film (SiON film).

Then, the oxide semiconductor layer 4 is formed. The oxide semiconductor layer 4 is formed by a sputtering method as mentioned above. It may preferably be formed by a DC (Direct Current) sputtering method or a RF (Radio Frequency) sputtering method using a sputtering target having the same composition as the oxide semiconductor layer 4. Alternatively, the deposition may also be carried out by a co-sputtering method.

When forming the oxide semiconductor layer 4, partial pressure of oxygen is controlled to 15 volume % or lower as described above in detail.

Then the oxide semiconductor layer 4 is subjected to patterning by photolithography and wet etching. Just after the patterning, heat treatment (pre-annealing) may be carried out for the purpose of improving the quality of the oxide semiconductor layer 4. The pre-annealing conditions may be, for example, such that the temperature is from 250 to 350° C. and the time is from 15 to 120 minutes. Preferably the temperature is from 300 to 350° C. and the time is from 60 to 120 minutes. By the pre-annealing, on-state current and field-effect mobility as the transistor characteristics increase and the transistor performance improves.

After the pre-annealing, for example a silicon oxide film (SiO₂ film) may be formed as the passivation film 5 for the purpose of protection of the surface of the oxide semiconductor layer 4 by the above-described method.

Then patterning by photolithography and wet etching is carried out in order to electrically connect the oxide semiconductor layer 4 to the source-drain electrode 6 which is successively formed.

Next the source-drain electrode 6 is formed. The kind of the source-drain electrode 6 is not particularly limited, and those which have widely been used can be employed. For example, similarly to the gate electrode 2, metals such as Al and Cu or their alloys may be used. A Mo thin film may also be used as in an example described below.

The source-drain electrode 6 may be formed by, for example, a deposition of the metal thin film by magnetron sputtering, followed by patterning using a lift-off method.

Then, the surface passivation film (insulator film) 7 is formed on the source-drain electrode 6. The surface passivation film 7 may be formed using, for example, a CVD (Chemical Vapor Deposition) method. For the surface passivation layer 7, there can be used a silicon oxide film (SiO₂ film), a silicon nitride film (SiN film), a silicon oxynitride film (SiON film), and a laminate of these.

Then, the transparent conductive film 8 is formed after forming a contact hole in the surface passivation film 7 by photolithography and dry etching. The kind of the transparent conductive film 8 is not particularly limited, and there can be used those which have usually been used.

The present invention includes a display device comprising the TFT. Examples of the display device include a liquid crystal display and an organic EL display.

The present application claims the benefit of priority based on Japanese Patent Application No. 2013-47367 filed on Mar. 8, 2013. The entire contents of the specification of Japanese Patent Application No. 2013-47367 filed on Mar. 8, 2013 are incorporated herein by reference.

### EXAMPLES

The present invention is described hereinafter more specifically by way of Examples, but the present invention is not limited to the following Examples. The present invention can be put into practice after appropriate modifications or variations within a range meeting the gist described above and below, all of which are included in the technical scope of the present invention.

### Example 1

In this Example, TFTs were fabricated and mobility was measured as follows. Defect density was determined by the ICTS method. The TFTs used in the present Example had the same structure as shown in FIG. 1 except that they did not have a passivation film to protect a surface of the oxide semiconductor layer (ITGZO thin film).

First, a Mo thin film of 100 nm in thickness was deposited on a glass substrate (“EAGLE XG” available from Corning Inc, having a diameter of 100 mm and a thickness of 0.7 mm), followed by patterning of generally-known method to obtain a gate electrode. The Mo thin film was deposited using a pure Mo sputtering target by a RF sputtering method under the conditions: deposition temperature, room temperature; sputtering power, 300 W; carrier gas, Ar; and gas pressure, 2 mTorr.

Next, a SiO₂ film of 250 nm in thickness was formed as a gate insulator film. The gate insulator film was formed by a plasma CVD method under the conditions: carrier gas, a mixed gas of SiH₄ and N₂O; plasma power, 300 W; and deposition temperature, 320° C.

Subsequently, an ITGZO thin film was deposited as the oxide semiconductor layer by sputtering method using an ITGZO sputtering target under the following conditions. Thickness of the ITGZO thin film was 40 nm and composition was In:Sn:Ga:Zn=16.6:19.4:17:47.1 in atomic ratio.

### (Deposition Conditions of ITGZO Thin Film)

Sputtering apparatus: “CS-200” available from ULVAC, Inc.

Substrate temperature: room temperature

Gas pressure: 1 mTorr

Oxygen partial pressure: [O₂/(Ar+O₂)]×100=4 volume %,
10 volume %, 20 volume %, 30 volume %

After the oxide semiconductor layer was deposited in the manner described above, patterning was carried out by photolithography and wet etching. “ITO-07N,” (a mixed solution of oxalic acid and water) available from Kanto Chemical Co., Inc., was used as a wet etchant at a temperature of 40° C.

After patterning of the oxide semiconductor layer, pre-annealing treatment was carried out to improve the film quality. The pre-annealing was carried out at 350° C. in a water vapor atmosphere under atmospheric pressure for 1 hour.

Then, a source-drain electrode was deposited by a lift-off method using pure Mo. Specifically, after patterning was carried out using a photoresist, a Mo thin film having a thickness of 100 nm was deposited by a DC sputtering method. The deposition condition of the Mo thin film for a source-drain electrode was the same as that used in the case of the gate electrode described above. An unnecessary photoresist was then removed in acetone with an ultrasonic washing device, to obtain each of the TFT having a channel length of 10 μm and a channel width of 200 μm.

After the formation of source-drain electrode in this way, a surface passivation film was formed for the purpose of protecting the oxide semiconductor layer. A laminate film having a total thickness of 350 nm consisting of a SiO₂ film having a thickness of 100 nm and a SiN having a thickness of 150 nm was formed as the surface passivation layer. The formation of the SiO₂ and SiN films was carried out by a plasma CVD method using “PD-220NL” available from SAMCO Inc. The SiO₂ film and the SiN film were formed in this order in the present Example. A mixed gas of N₂O and SiH₄ was used for the formation of the SiO₂ film, and a mixed gas of SiH₄, N₂ and NH₃ was used for the formation of the SiN film. The film formation temperature was set to 230° C. during forming the initial 100 nm of the SiO₂ film of 200 nm in thickness. The film formation temperature was thereinafter set to 150° C. for the deposition of the rest of 100 nm of the SiO₂ film and the SiN film of 10 nm in thickness. The film formation power was 100 W in all the deposition.

Then, a contact hole to be used for probing to evaluate transistor characteristics was formed in the surface passivation film by photolithography and dry etching. The TFT was thus fabricated.

By using each TFT thus obtained, transistor characteristics (drain current-gate voltage characteristics, I_{d}-V_{g} characteristics), field-effect mobility, and defect density were measured.

### (1) Measurement of Transistor Characteristics

The transistor characteristics (TFT characteristics) were measured using a semiconductor parameter analyzer “4156C” available from Agilent Technology. The measurement was conducted by probing the sample through the contact hole. The detailed measurement conditions were as follows:

Source voltage: 0 V

Drain voltage: 10 V

Gate voltage: from −30 to 30 V (measurement interval: 0.25 V)

Substrate temperature: room temperature

### (2) Field-Effect Mobility μ_{FE}

The field-effect mobility μ_{FE} was derived in the saturation region where V_{d}>V_{g}−Vₜₕ from the TFT characteristics. In the saturation region, the filed-effect mobility μ_{FE} is derived by the expression described below, in which V_{g} and Vₜₕ are the gate voltage and the threshold voltage, respectively; I_{d} is the drain current; L and W are the channel length and channel width of a TFT element, respectively; Cᵢ is the static capacitance of the gate insulator layer; and μ_{FE} is the field-effect mobility. In the present example, the field-effect mobility μ_{FE} was derived from the drain current-gate voltage characteristics (I_{d}-V_{g} characteristics) around gate voltages falling in the saturation region.

$${μ}_{FE} = \frac{\partial {I}_{d}}{\partial {V}_{g}} ( \frac{L}{{C}_{i} W ( {V}_{g} - {V}_{th} )} ) \qquad [ Expression 1 ]$$

### (3) Measurement of Defect Density by ICTS Method

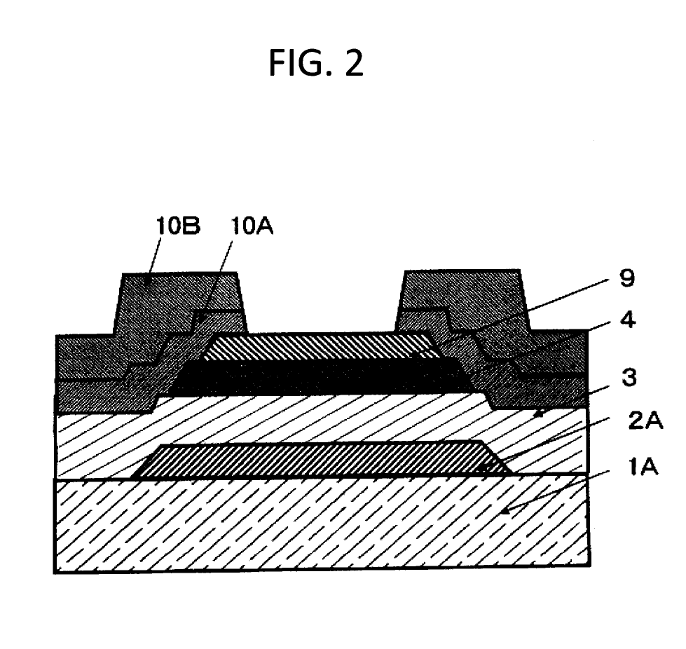

In the ICTS method, when an electron trap once captured by applying a forward pulse in a semiconductor junction in a reverse-biased state is returning to the reverse bias state again, a process of releasing the trapped electrons via a thermal excitation process is detected as transient changes in the junction capacitance. The method is to examine the property of the trap. In the present example, the defect density was measured by the ICTS method using a MIS structure element shown in FIG. 2. An electrode constituting the MIS had an area of 1 mm in diameter. Measurement conditions were specifically as follows. In FIG. 2, 1A is the glass substrate, 2A is the Mo electrode, 3 is the gate insulator film, 4 is the oxide semiconductor layer, 9 is the Mo electrode of 1 mm in diameter, and 10A and 10B indicate the passivation films.

ICTS measurement device: FT1030 HERA-DLTS system available from PhysTech GmbH

Measurement temperature: 210 K

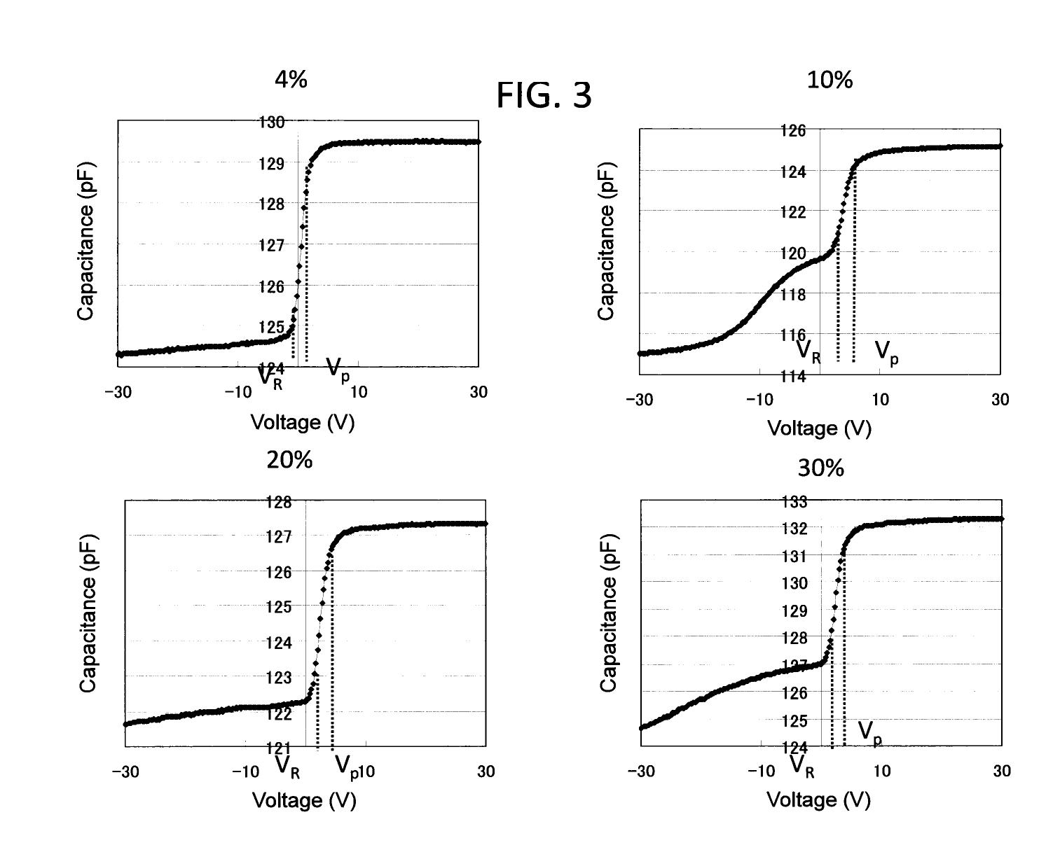

Reverse bias: Shown in FIG. 3

Pulse voltage: Shown in FIG. 3

Pulse time: 100 msec

Frequency of measurement: 1 MHz

Measurement time: 5×10⁻⁴ to 10 seconds

The reverse bias and the pulse bias for each of the ICTS measurements of samples prepared at partial pressures of oxygen of 4 volume %, 10 volume %, 20 volume %, and 30 volume % were determined from voltage value indicated in C-V (capacitance-voltage) curves of FIG. 3. The details are as follows. In FIG. 3, a range between dotted lines corresponds to the variation in the thickness of depletion layer. In FIG. 3, % means volume %.

The reverse bias was −0.25 V and the pulse bias was 1.25 V when the partial pressure of oxygen was 4 volume %.

The reverse bias was 2 V and the pulse bias was 5.5 V when the partial pressure of oxygen was 10 volume %.

The reverse bias was 1.5 V and the pulse bias was 3.5 V when the partial pressure of oxygen was 20 volume %.

The reverse bias was 1.5 V and the pulse bias was 3.5 V when the partial pressure of oxygen was 30 volume %.

The defect density in the present Example was determined by dividing a defect density derived from the variation of ΔC during the measurement time by a correction factor expressed using the following expression.

Correction factor=(Xᵣ−Xₚ)/Xᵣ

wherein Xᵣ represents a thickness of depletion layer under the reverse bias V_{R}, and Xₚ represents a thickness of depletion layer under the pulse bias V_{P}.

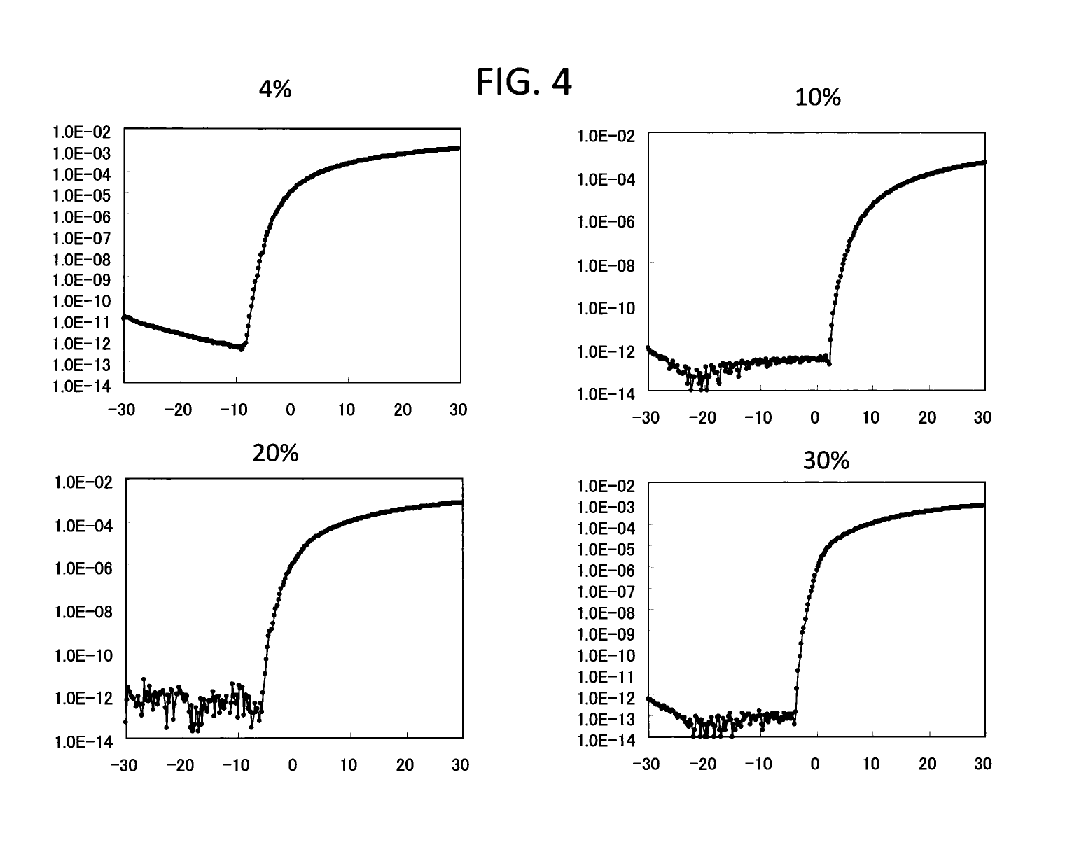

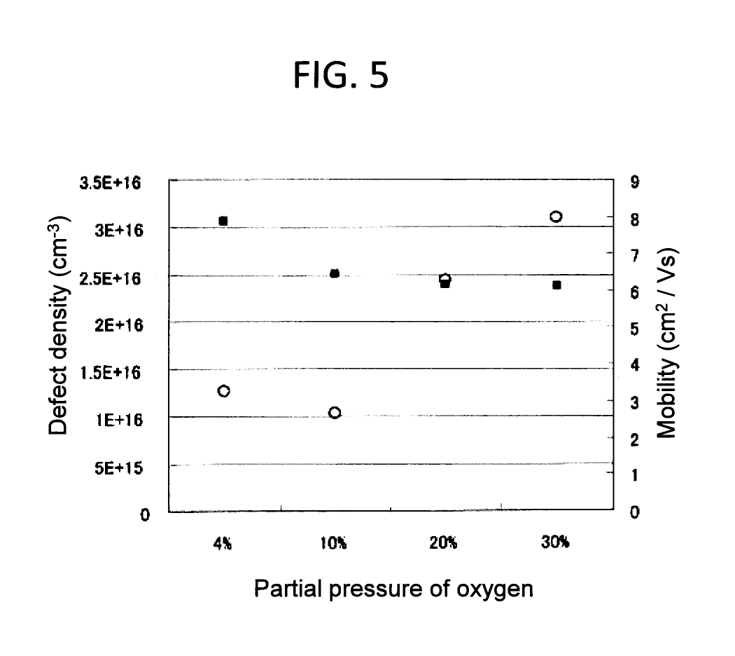

These results are shown in FIG. 4, FIG. 5, and Table 1. In FIG. 4, FIG. 5, and Table 1, % means volume %.

FIG. 4 are graphs showing I_{d}-V_{g} characteristics of the ITGZO films formed under the partial pressures of oxygen of 4 volume %, 10 volume %, 20 volume %, and 30 volume %. FIG. 5 is a graph of the defect density and mobility plotted for each of the partial pressure of oxygen. Open circles ∘ indicate results of the defect density whereas filled square ▪ indicate results of the mobility in FIG. 5.

TABLE 1

| Partial pressure of oxygen when | Defect density NT | Mobility |
|---|---|---|
| forming the film | (cm⁻³) | (cm²/Vs) |
| 4% | 1.28 × 10¹⁶ | 7.9 |
| 10% | 1.06 × 10¹⁶ | 6.5 |
| 20% | 2.45 × 10¹⁶ | 6.2 |
| 30% | 3.10 × 10¹⁶ | 6.1 |

FIG. 4 is referred to firstly. The horizontal axis is V_{g} (V) and the vertical axis is I_{d} (A) in FIG. 4. “1.0E-05” for example represents 1.0×10⁻⁵ in FIG. 4. As shown in FIG. 4, transistor characteristics of TFTs formed with 20 volume % and 30 volume % partial pressures of oxygen apparently the same.

In reality, however, the defect density and the mobility significantly varied for each of the partial pressures of oxygen as shown in FIG. 5 and Table 1. Specifically, it was found that the mobility increases as the partial pressure of oxygen when forming the ITGZO films decreases in the range of 4 to 30 volume % in the present example. The defect density, on the other hand, showed the minimum value when the partial pressure of oxygen was 10 volume % then slightly increased thereafter. Generally, the defect density was likely to decrease as the partial pressure of oxygen decreased.

According to the measurement conditions of the present example, it was found that the high mobility can be secured while keeping the defect density low by controlling the partial pressure of oxygen to 15 volume % or lower, preferably 10 volume % or lower, and more preferably 4 volume % or lower.

As shown above, it is extremely important to derive defect density in controlling the mobility of the TFT. It was demonstrated that a TFT having both low defect density and high mobility can be obtained by appropriately controlling partial pressure of oxygen when forming the ITGZO as in the present invention.

### EXPLANATION OF REFERENCE NUMERALS

1 Substrate
2 Gate electrode
3 Gate insulator film
4 Oxide semiconductor layer
5 Passivation film (SiO₂ film)
6 Source-drain electrode
7 Surface passivation film (insulator film)
8 Transparent conductive film
1A Glass substrate
2A Mo electrode
9 Mo electrode of 1 mm in diameter
10A, 10B Passivation film

1: An oxide configured to be used as a semiconductor layer in a thin film transistor, the oxide comprising:
one or more metal elements selected from the group consisting of In, Sn, Ga, and Zn;
wherein:
the oxide is formed as a semiconductor layer in a thin film transistor at a partial pressure of oxygen of 15 volume % or lower but not including 0 volume %;
the oxide has a defect density of 2×10¹⁶ cm⁻³ or smaller; and
the oxide has a mobility of 6.2 cm²/Vs or larger.

2: The oxide according to claim 1, wherein:
In is present in an amount of 3 atomic % to 25 atomic %,
Sn is present in an amount of 15 atomic % to 30 atomic %,
Ga is present in an amount of 10 atomic % to 50 atomic %,
Zn is present in an amount of 3 atomic % to 25 atomic %; and
the atomic % is based on a total content of the one or more metal elements.

3: A thin film transistor comprising the oxide according to claim 1 as a semiconductor layer of the thin film transistor.

4: A display device comprising the thin film transistor according to claim 3.
